(19) United States
(12) Patent Application Publication
(10) Pub. No.: US 2016/0216819 A1
(43) Pub. Date: Jul. 28, 2016

(54) DISPLAY DEVICE AND METHOD FOR PROTECTING WINDOW THEREOF

(71) Applicant: SAMSUNG DISPLAY CO., LTD., Yongin-City (KR)

(72) Inventors: Dong-Wook CHOI, Hwaseong-si (KR); Jong Ho CHONG, Hwaseong-si (KR)

(21) Appl. No.: 14/817,436

(22) Filed: Aug. 4, 2015

(30) Foreign Application Priority Data
Jan. 22, 2015 (KR) 10-2015-0010846

(51) Int. Cl. G06F 3/041

(52) U.S. Cl. CPC G06F 3/0412; G06F 2203/04107

(57) ABSTRACT

A touch-enabled display device includes a display panel for displaying an image, a touch sensitive region being disposed at a first surface of the display panel, a window on the display panel and covering the touch sensitive region, and a protecting layer on the window, the protecting layer including a shape memory polymer layer.

### CROSS-REFERENCE TO RELATED APPLICATION

Korean Patent Application No. 10-2015-0010846, filed on Jan. 22, 2015, in the Korean Intellectual Property Office, and entitled: “Display Device and Method for Protecting Window Thereof,” is incorporated by reference herein in its entirety.

### BACKGROUND

1. Field

Embodiments relate to a display device and a method for protecting a window thereof.

2. Description of the Related Art

Examples of display devices include a liquid crystal display (LCD), a plasma display panel (PDP), an organic light emitting diode (OLED) device, a field effect display (FED), an electrophoretic display device, and the like. Such a display may be mounted with a touch panel used as an input device. The touch panel may be classified into a resistive type touch panel, a capacitive type touch panel, an electro-magnetic type touch panel, and the like, depending on a method of sensing a touch.

The above information disclosed in this Background section is only for enhancement of understanding of the background of the disclosure and therefore it may contain information that does not form the prior art that is already known in this country to a person of ordinary skill in the art.

### SUMMARY

Embodiments are directed to a touch-enabled display device, including a display panel for displaying an image, a touch sensitive region being disposed at a first surface of the display panel, a window on the display panel and covering the touch sensitive region, and a protecting layer on the window, the protecting layer including a shape memory polymer layer.

The shape memory polymer layer may be made of a flexible material, and may restore its shape when an electrical signal is applied thereto.

The display device may be made of a flexible material, and the electrical signal may be applied to the shape memory polymer layer in the case in which an object touches the protecting layer.

The shape memory polymer layer may be configured of a plurality of unit cells, and the plurality of unit cells may be arranged in a lattice structure on the window.

The electrical signal may be applied to each of the plurality of unit cells.

The protecting layer may further include a wiring part applying the electrical signal to the shape memory polymer layer.

The display device may further include a controlling unit controlling the wiring part so that the electrical signal is applied to a region corresponding to a touch point by the object in the shape memory polymer layer.

The touch sensitive region may be in a touch panel that includes a sensing unit sensing the touch point, and the controlling unit may apply the electrical signal through the wiring part depending on information on the touch point transferred from the sensing unit.

The sensing unit may sense a touch prediction point as the touch point just before the object touches the protecting layer.

The display device may be foldable, the electrical signal may not be applied to the shape memory polymer layer in a state in which the display device is folded, and the electrical signal may be applied to the shape memory polymer layer in a state in which the display device is unfolded.

The display device may further include a polarizer facing a surface of the display panel.

The protecting layer may be an outermost layer of the display device so as to be directly contacted by a user.

Embodiments are also directed to a method for protecting a window of a display device so as to prevent the window from being damaged when an object touches the display device over the window, the display device including a display panel and a touch sensitive region, a window on the display panel, and a shape memory polymer layer on the window, the method including sensing the touch over the window by the object, and transferring a control signal to the shape memory polymer layer such that the shape memory polymer layer restores its shape.

In the sensing of the touch, a touch prediction point may be sensed just before the object touches the display device over the window.

The sensing of the touch may include calculating a coordinate value of a touch point, and, in the transferring of the control signal, the control signal may be transferred to a region corresponding to the coordinate value in the shape memory polymer layer.

The shape memory polymer layer may restore its shape when an electrical signal is applied thereto, and, in the transferring of the control signal, the electrical signal may be applied to the shape memory polymer layer.

The shape memory polymer layer may be configured of a plurality of unit cells, and the plurality of unit cells may be arranged in a lattice structure on the window, and, in the transferring of the control signal, the electrical signal may be applied to unit cells of a region corresponding to the touch point in the shape memory polymer layer.

### BRIEF DESCRIPTION OF THE DRAWINGS

Features will become apparent to those of skill in the art by describing in detail example embodiments with reference to the attached drawings in which:

FIG. 1 illustrates a cross-sectional view of a display device according to an example embodiment.

FIG. 2 illustrates an equivalent circuit diagram of one pixel of a display panel shown in FIG. 1.

FIG. 3 illustrates a cross-sectional view of the display panel shown in FIG. 1.

FIG. 4 illustrates a cross-sectional view showing a form in which a protecting layer of the display device according to an example embodiment is operated.

FIG. 5 illustrates a plan view of the display device according to an example embodiment.

FIG. 6 illustrates a cross-sectional view taken along line VI-VI′ of FIG. 5.

FIG. 7 illustrates a flow chart of a method for protecting a window of a display device according to an example embodiment.

FIGS. 8 to 11 illustrate views sequentially showing processes of protecting the window of the display device according to an example embodiment.

<Description of symbols>

| | |
|---|---|
| 21 scanning signal line | 71 data line |
| 72 driving voltage line | 121 second insulating layer |
| 122 electrode part | 123 first insulating layer |
| 110 window | 120 touch panel |
| 130a, 130b, 130c resin layer | 140 polarizer |
| 150 display panel | 151 insulation substrate |
| 152 contact hole | 153 passivation layer |
| 155 pixel electrode | 156 organic emission layer |
| 157 common electrode | 158 organic layer |
| 170 protecting layer | 171 shape memory polymer layer |
| 172 wiring part | 180 sensing unit |
| 190 controlling unit | |

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art.

In the drawing figures, the dimensions of layers and regions may be exaggerated for clarity of illustration. Like reference numerals refer to like elements throughout.

It will be understood that when an element such as a layer, film, region, or substrate is referred to as being “on” another element, it can be directly on the other element or intervening elements may also be present.

In addition, throughout the present specification, unless explicitly described to the contrary, the word “comprise” and variations such as “comprises” or “comprising”, will be understood to imply the inclusion of stated elements but not the exclusion of any other elements. In addition, throughout the specification, the word “on” does not necessarily mean that any element is positioned at an upper side based on a gravity direction, but means that any element is positioned above or below a target portion.

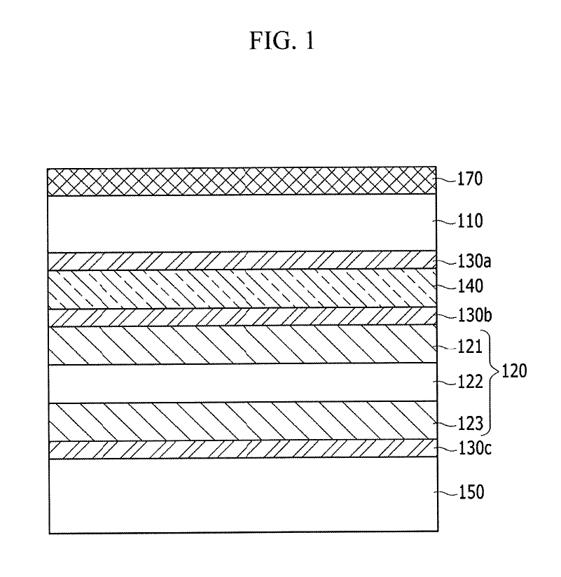

FIG. 1 is a cross-sectional view of a display device according to an example embodiment.

The display device according to an example embodiment is a display device capable of protecting a window by preventing a scratch, pressing or indentation, or the like, generated on a window due to a touch.

Referring to FIG. 1, the display device includes a display panel 150, resin layers 130a, 130b, and 130c, a touch panel 120, a polarizer 140, a window 110, and a protecting layer 170.

According to an example embodiment, the display panel 150 is a component displaying an image.

Hereinafter, although the display panel 150 of an organic light emitting diode (OLED) device including an organic light emitting element will be described, a display panel is not limited thereto, but may be a display panel of a liquid crystal display (LCD), a plasma display panel (PDP), a field effect display (FED), an electrophoretic display device, or the like.

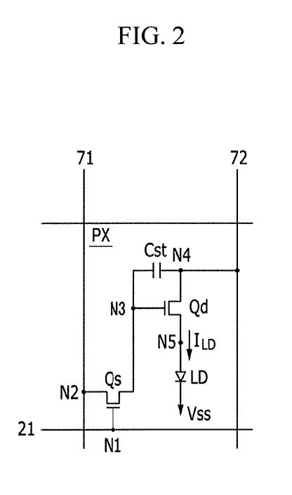

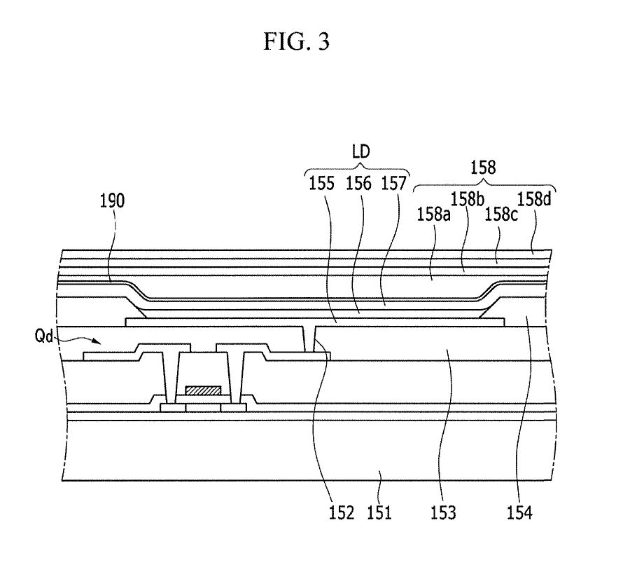

FIG. 2 is an equivalent circuit diagram of one pixel of a display panel shown in FIG. 1, and FIG. 3 is a cross-sectional view of the display panel shown in FIG. 1.

Referring to FIG. 2, the display panel 150 includes a plurality of signal lines 21, 71, and 72, and pixels PXs connected to the plurality of signal lines. The pixels PX may be any one of a red pixel R, a green pixel G, and a blue pixel B.

The signal lines include scanning signal lines 21 transferring gate signals (or scanning signals), data lines 71 transferring data signals, driving voltage lines 72 transferring driving voltages, and the like. The scanning signal lines 21 are extended in approximately a row direction and are substantially in parallel with each other, and the data lines 71 are extended in approximately a column direction and are substantially in parallel with each other. Although an example in which the driving voltage lines 72 are extended in approximately the column direction has been shown, the driving voltage lines 72 may be extended in the row direction or the column direction or be formed in a net shape.

One pixel PX includes a switching transistor Qs, a driving transistor Qd, a storage capacitor Cst, and an organic light emitting element LD.

The switching transistor Qs has a control terminal N1, an input terminal N2, and an output terminal N3, wherein the control terminal N1 is connected to the scanning signal line 21, the input terminal N2 is connected to the data line 71, and the output terminal N3 is connected to the driving transistor Qd. The switching transistor Qs transfers the data signal received from the data line 71 to the driving transistor Qd in response to the scanning signal received from the scanning signal line 21.

The driving transistor Qd also has a control terminal N3, an input terminal N4, and an output terminal N5, wherein the control terminal N3 is connected to the switching transistor Qs, the input terminal N4 is connected to the driving voltage line 72, and the output terminal N5 is connected to the organic light emitting element LD. The driving transistor Qd allows an output current I_{LD} of which a magnitude is changed depending on a voltage applied between the control terminal N3 and the output terminal N5 to flow.

The capacitor Cst is connected between the control terminal N3 and the input terminal N4 of the driving transistor Qd. The capacitor Cst is charged with the data signal applied to the control terminal N3 of the driving transistor Qd, and maintains the data signal even after the switching transistor Qs is turned off.

The organic light emitting element LD, which is, for example, an organic light emitting diode (OLED), has an anode connected to the output terminal N5 of the driving transistor Qd and a cathode connected to a common voltage Vss. The organic light emitting element LD emits light of which strength is changed depending on the output current I_{LD} of the driving transistor Qd to display an image. The organic light emitting element LD may contain an organic material uniquely emitting any one or one or more of primary colors such as three primary colors, or the like, of red, green, and blue, and the OLED device displays a desired image by the spatial sum of these colors.

The switching transistor Qs and the driving transistor Qd may be n-channel field effect transistors (FETs). Alternatively, at least one of the switching transistor Qs and the driving transistor Qd may be a p-channel field effect transistor. In addition, connection relationships between the transistors Qs and Qd, the capacitor Cst, and the organic light emitting element LD may be changed.

Next, a cross section of a general display panel 150 will be described in detail with reference to FIG. 3.

Referring to FIG. 3, a driving transistor Qd is on an insulation substrate 151 made of transparent glass, plastic, or the like. In addition to the driving transistor Qd, a plurality of signal lines (not shown), a plurality of switching transistors (not shown), and the like, may be further formed on the insulation substrate 151.

A passivation layer 153 that may be made of an inorganic material or an organic material is on the driving transistor Qd. In the case in which the passivation layer 153 is made of the organic material, a surface of the passivation layer 153 may be flat. A contact hole 152 exposing a portion of the driving transistor Qd is formed in the passivation layer 153. A pixel electrode 155 is on the passivation layer 153. The pixel electrode 155 includes a reflecting electrode and a transparent electrode formed on the reflecting electrode. The reflecting electrode may be made of a metal having high reflectivity, such as silver (Ag) or aluminum (Al), or an alloy thereof, etc., and the transparent electrode may be made of a transparent conductive oxide such as an indium tin oxide (ITO), an indium zinc oxide (IZO), or the like.

A pixel definition layer 154 covering the surrounding of edges of the pixel electrode 155 is formed on the passivation layer 153.

An organic emission layer 156 is on the pixel electrode 155, and a common electrode 157 is formed on the organic emission layer 156 and the pixel definition layer 154.

The organic emission layer 156 may further include organic layers (not shown) for efficiently transferring carriers of holes or electrons to an emission layer (not shown) in addition to the emission layer in which light is actually emitted. These organic layers may be a hole injection layer or a hole transport layer positioned between the pixel electrode 155 and the emission layer or an electron injection layer and an electron transport layer positioned between the common electrode 157 and the emission layer.

An overcoat 190 covering and protecting the common electrode 157 may be formed of an organic layer on the common electrode 157.

A thin film encapsulation layer 400 is on the overcoat 190. The thin film encapsulation layer 400 seals and protects an organic light emitting element LD and a driving circuit part on the substrate 151 from the outside.

The thin film encapsulation layer 400 includes encapsulation organic layers 158a and 158c and encapsulation inorganic layers 158b and 158d alternately stacked one by one. Although the case in which two encapsulation organic layers 158a and 158c and two encapsulation inorganic layers 158b and 158d are alternately stacked one by one to configure the thin film encapsulation layer 400 has been shown by way of example in FIG. 3, the present disclosure is not limited thereto.

According to an example embodiment, the touch panel 120 may be disposed above the touch panel 150, and may sense a touch input from the outside. The touch panel 120 may be a capacitive type touch panel. However, the touch panel 120 is not limited thereto, but a resistive type touch panel or an electro-magnetic type touch panel.

Referring to FIG. 1, the touch panel 120, which is a general capacitive type touch panel, may include a first insulating layer 123, an electrode part 122, and a second insulating layer 121.

The first insulating layer 123, which is a component serving as a substrate, may be an insulating substrate made of glass, polyethyleneterephthalate (PET), or the like.

The electrode part 122 on the first insulating layer 123 may include a plurality of X electrodes (not shown) and Y electrodes (not shown) arranged in X and Y directions, respectively, when viewed from the top.

The plurality of X and Y electrodes may detect changes in capacitances in each electrode by a finger or pen touch. The electrode part 122 may be made of a material having high transmittance, for example, a transparent conductive material such as an indium tin oxide (ITO), or the like.

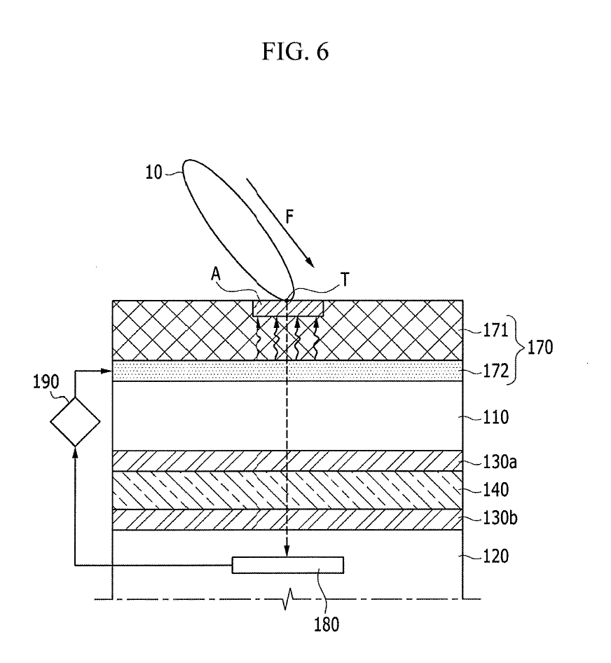

A sensing unit 180 (See FIG. 6; to be described below) may be included in the electrode part 122.

The second insulating layer 121 may be formed on the electrode part 122 to serve to protect the electrode part 122. The second insulating layer 121 may be made of an insulating material such as PET, or the like.

Referring to FIG. 1, the polarizer 140 is disposed above the touch panel 120. The polarizer 140 converts an optical axis of light output to the outside through the display panel 150 and the touch panel 120. Generally, the polarizer has a structure in which transparent protecting films are stacked on both surfaces or one surface of the polarizer made of a polyvinyl alcohol based resin.

In more detail, the polarizer 140 has a structure in which polyvinyl alcohol (hereinafter, referred to as PVA) based molecular chains are aligned in a predetermined direction and a triacetyl cellulose (TAC) film is bonded as a protecting film to a polarizer having a structure including an iodine based compound or a dichromatic polarization material. The polarizer and the protecting film are generally bonded to each other by a resin based adhesive made of a polyvinyl alcohol aqueous solution.

However, the polarizer 140 is not limited thereto, but may have various structures.

In addition, although the case in which the polarizer 140 is disposed above the touch panel 120 has been shown in FIG. 1, the polarizer 140 is not limited to being disposed above the touch panel 120, but may also be disposed between the display panel 150 and the touch panel 120 depending on a display device.

The window 110 may be disposed above the touch panel 120. The window 110 serves to protect the touch panel 120 and the display panel 150 positioned therebelow.

Referring to FIG. 1, the resin layers 130a, 130b, and 130c are formed between the display panel 150 and the touch panel 120, between the touch panel 120 and the polarizer 140, and between the polarizer 140 and the window 110, respectively.

The resin layer 130c positioned between the display panel 150 and the touch panel 120 may bond the display panel 150 and the touch panel 120 to each other. In addition, the resin layer 130b positioned between the touch panel 120 and the polarizer 140 may bond the touch panel 120 and the polarizer 140 to each other, and the resin layer 130a positioned between the polarizer 140 and the window 110 may bond the polarizer 140 and the window 110 to each other.

The resin layers 130a, 130b, and 130c may be formed by curing liquid resins.

According to an example embodiment, the protecting layer 170 may be formed on the window 110.

The protecting layer 170, which is a component protecting the window 110 so that a scratch, pressing, or the like is not generated on the window 110, may include a shape memory polymer (SMP) layer, according to an example embodiment.

A shape memory polymer, which is a material maintaining a predetermined shape under a specific condition in which predetermined stimulus such as a temperature, an electric field, and the like, are applied, is a polymer having a property that it returns to its original shape when the specific condition is satisfied even though it is deformed by external impact.

The shape memory polymer layer may be made of a transparent material so as not to have an influence on visibility.

According to an example embodiment, the shape memory polymer layer may be made of a flexible material, and may restore its shape when an electrical signal is applied thereto.

The shape memory polymer layer may be made of the flexible material in order to implement flexibility of the display device, and may be made of a polymer material maintained in a flat shape under a condition in which the electrical signal is applied thereto. Therefore, although the shape memory polymer layer may be deformed under a condition in which the electrical signal is not applied thereto, it may be restored to the flat shape when the electrical signal is applied thereto.

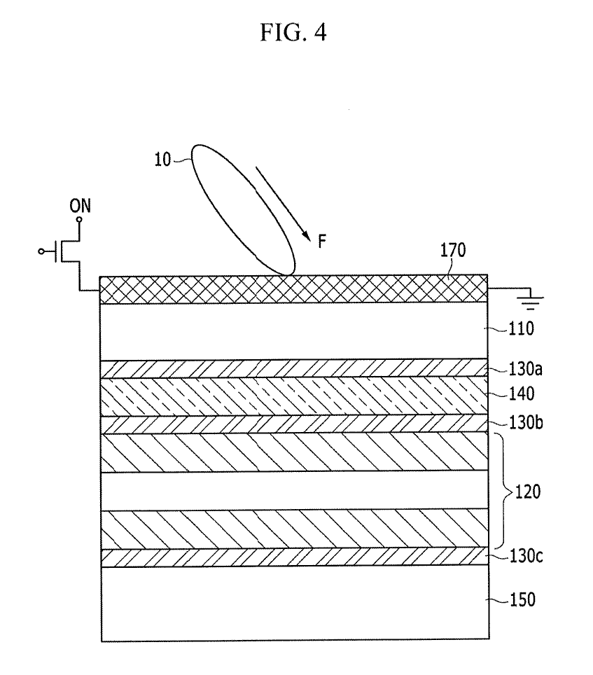

FIG. 4 is a cross-sectional view showing a form in which a protecting layer of the display device according to an example embodiment is operated.

Referring to FIG. 4, in the case in which an object 10 such as a finger, a pen, or the like, touches the window 110 in order to conduct an input command to the display device, external force F acts on the window 110 due to the touch, such that a scratch, pressing, or the like, may be generated at a touch point on the window 110.

For example, in the case in which the window is made of a plastic material having flexibility, damage to the window may be intensified.

According to an example embodiment, since the protecting layer 170 is formed on the window 110, in the case in which the object 10 touches the window 110, the object 10 touches the protecting layer 170 rather than the window 110. Therefore, a scratch or pressing due to the touch of the object 10 is not generated on the window 110, but is generated on the protecting layer 170 made of a flexible material.

In this case, as shown in FIG. 4, when the electrical signal is applied to the shape memory polymer layer included in the protecting layer 170, the shape memory polymer layer of which a surface is deformed due to the scratch, the pressing, or the like, by the external force F of the object 10 may be restored to an original shape such as a flat shape.

As a result, the protecting layer 170 including the shape memory polymer layer is formed on the window 110, thereby making it possible to protect the window 110 made of the flexible material from the scratch, or the like.

Next, an illustrative configuration of the protecting layer 170 will be described in detail.

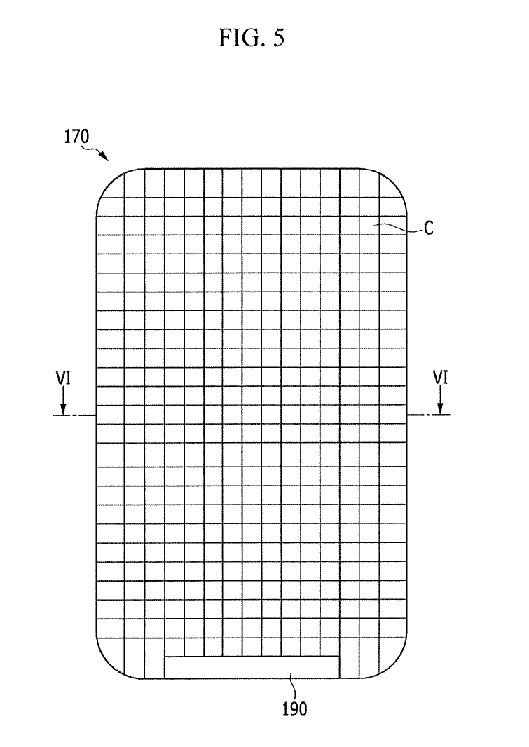

FIG. 5 is a plan view of the display device according to an example embodiment, and FIG. 6 is a cross-sectional view taken along line VI-VI′ of FIG. 5.

Referring to FIGS. 5 and 6, the protecting layer 170 may include the shape memory polymer layer 171 and a wiring part 172.

According to an example embodiment, as shown in FIG. 5, the shape memory polymer layer 171 may be configured of a plurality of unit cells C.

The plurality of unit cells may be arranged in a lattice structure on the window 110, and the electrical signal may be applied to each of the plurality of unit cells.

Therefore, the shape memory polymer layer 171 may be uniformly positioned at all positions on the window 110, and may more accurately and efficiently restore the shape.

That is, the electrical signal may be selectively applied to only cells in which a shape needs to be restored among the plurality of unit cells configuring the shape memory polymer layer.

The wiring part 172 is a component applying the electrical signal to the above-mentioned shape memory polymer layer 171.

The wiring part 172 may apply the electrical signal to each of the plurality of unit cells configuring the shape memory polymer layer, and a circuit including electrodes, wirings, and the like, may be configured in the wiring part 172.

The wiring part 172 may be formed of a layer disposed below the shape memory polymer layer 171, as shown in FIG. 6, but is not limited thereto.

The wiring part 172 may be made of a transparent material, for example, a transparent conductive oxide such as an indium tin oxide (ITO), an indium zinc oxide (IZO), or the like.

The shape memory polymer layer 171 and the wiring part 172 described above may be patterned on the window 110 by a depositing process. However, a process of forming the shape memory polymer layer 171 and the wiring part 172 is not limited thereto.

Referring to FIGS. 5 and 6, an illustrative process in which a shape of the shape memory polymer layer 171 is restored will be described.

First, when the object 10 touches the shape memory polymer layer 171 while pressing the external force F to the shape memory polymer layer 171, the sensing unit 180 senses a touch point T and transfers the sensed touch point to a controlling unit 190.

Then, the controlling unit 190 transmits a control signal to the wiring part 172 so as to apply the electrical signal to a region A corresponding to the touch point T.

Therefore, the wiring part 172 applies the electrical signal to a cell corresponding to the region A corresponding to the touch point T among the plurality of unit cells configuring the shape memory polymer layer 171, and deformation such as the scratch, pressing, or the like, generated due to the touch is restored to a flat shape.

Meanwhile, according to an example embodiment, the sensing unit 180 sensing the touch point T may be provided in the touch panel 120, for example, the electrode part 122 (See FIG. 1) described above.

In addition, according to an example embodiment, the touch point T may be sensed just before the object 10 touches the protecting layer 170. For example, a hovering scheme may be used, thereby making it possible to sense a touch prediction point as the touch point T when the object 10 approaches the protecting layer 170, without performing a direct touch.

The display device according to another example embodiment may be foldable. In this case, the protecting layer 170 may be implemented in a scheme different from the above-mentioned scheme.

In a foldable display device, the electrical signal is not applied to the protecting layer 170 in the state in which the display device is folded, for example, in the case in which the display device is not being used, and is applied to the protecting layer 170 in the state in which the display device is unfolded, for example, in the case in which the display device is being used, thereby making it possible to always prevent the scratch or the pressing.

Next, a process of protecting the window using the display device according to an example embodiment will be described in more detail.

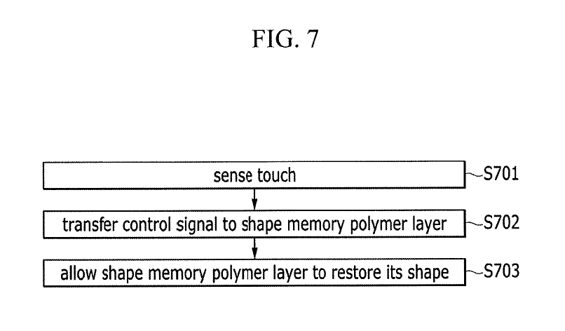

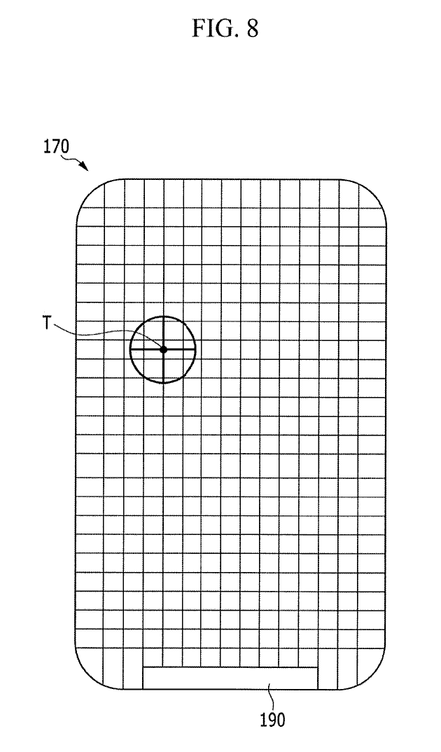

FIG. 7 is a flow chart of a method for protecting a window of a display device according to an example embodiment, and FIGS. 8 to 11 are views sequentially showing processes of protecting the window of the display device according to an example embodiment.

Referring to FIG. 7, in the display device according to an example embodiment, the window may be protected by sensing a touch of the object (S701), transferring a control signal to the shape memory polymer layer depending on a sensed touch signal (S702), and allowing the shape memory polymer layer receiving the control signal to restore the shape (S703).

In more detail, as shown in FIG. 8, in the case in which the object such as the finger, the pen, or the like, touches the protecting layer 170 on the window, the touch point T is sensed.

Here, according to an example embodiment, the touch point T may be sensed by the sensing unit 180 (See FIG. 6) provided in the touch panel.

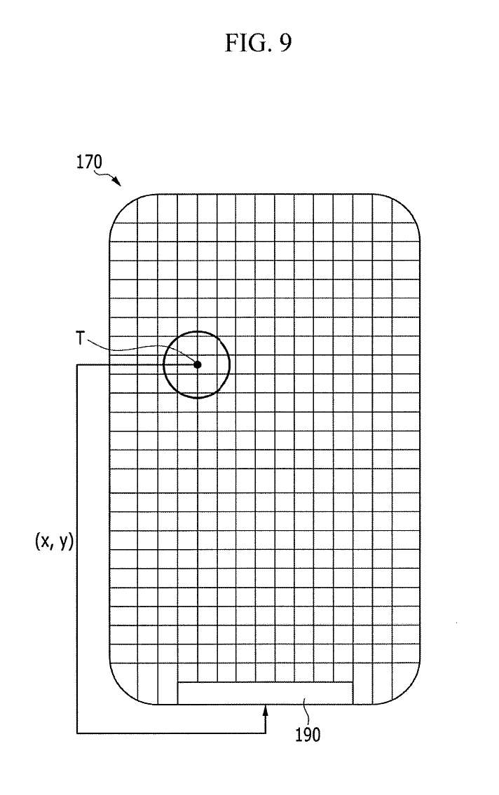

In addition, referring to FIG. 9, the sensing unit 180 may calculate (x, y) coordinate values of the touch point T, and the calculated (x, y) coordinate values of the touch point T may be transferred to the controlling unit 190.

The touch point T may be a touch prediction point sensed just before the object touches the window as well as a point sensed when the object directly touches the window, that is, the protecting layer 170.

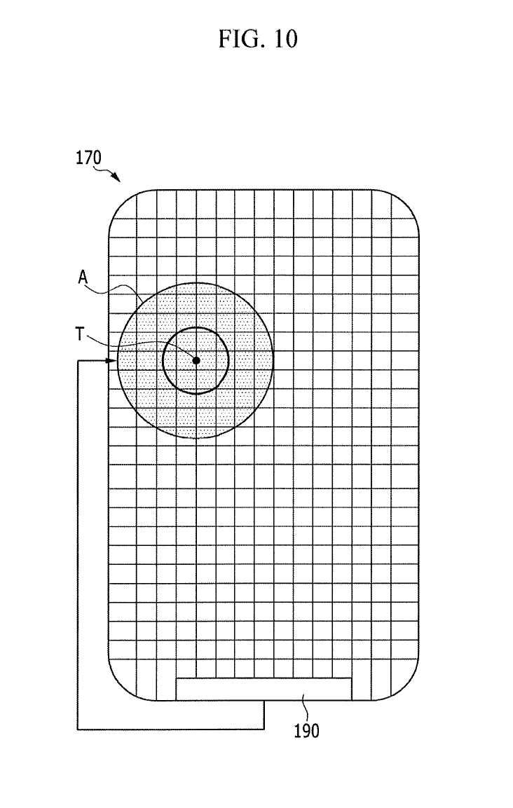

Then, referring to FIG. 10, the controlling unit 190 transfers the control signal to the shape memory polymer layer of the protecting layer 170 depending on transferred information on the touch point T.

The controlling unit 190 may calculate a corresponding region A of the shape memory polymer layer corresponding to the (x, y) coordinate values of the touch point T and apply the electrical signal to only the corresponding region A.

For example, the controlling unit 190 may apply the electrical signal to only cells belonging to the corresponding region A among the plurality of unit cells configuring the shape memory polymer layer.

Here, according to an example embodiment, the corresponding region A, which is a range calculated in consideration of deformation extended and generated up to positions adjacent to the touch point T based on the touch point T depending on external force applied to the touch point T, means a region calculated so as to sufficiently cover the deformation extended and generated up to the positions adjacent to the touch point T.

For example, in the case in which the external force applied to the touch point T is small, the corresponding region A corresponding to the touch point T may be relatively small, and in the case in which the external force applied to the touch point T is large, the corresponding region A corresponding to the touch point T may be relatively large.

As described above, when the electrical signal is transferred to the protecting layer 170, for example, the shape memory polymer layer having a property that it restores its shape by an electrical signal stimulus, the shape memory polymer layer restores its shape.

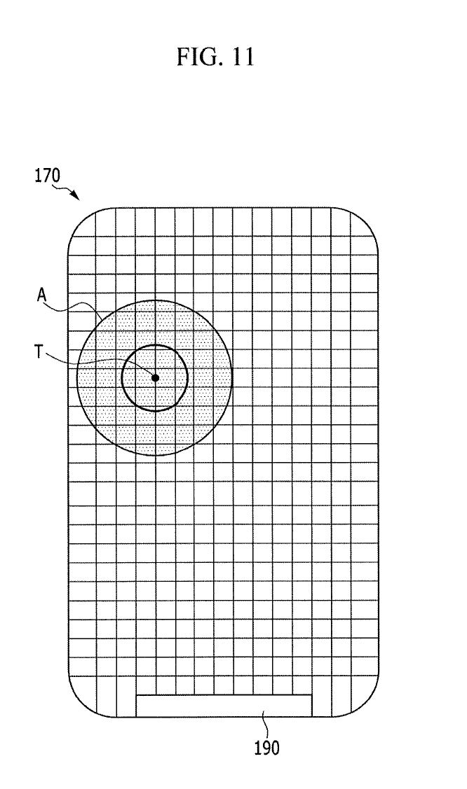

For example, referring to FIG. 11, when the electrical signal is transferred to the corresponding region A corresponding to the touch point T in the shape memory polymer layer configured of the plurality of unit cells, shapes of unit cells to which the electrical signal is transferred are restored, such that a shape of the corresponding region A may be restored.

As a result, when the object such as the finger, the pen, or the like, touches the window, it is possible to prevent the scratch, the pressing, or the like, from being generated on the window.

As described above, in the display device according to an example embodiment, the protecting layer 170 is on the window, thereby making it possible to prevent the scratch, the pressing, or the like, from being generated on the window made of the flexible material.

The protecting layer 170 includes the shape memory polymer layer of which the shape is restored to the flat shape when the electrical signal is applied thereto, such that the electrical signal is applied to the touch point, thereby making it possible to restore the shape of the touch point in which the deformation is generated.

In addition, the shape memory polymer layer is configured of the plurality of unit cells, thereby making it possible to more accurately and efficiently restore the shape of the touch point.

As a result, the window may be effectively protected from damage or deformation such as the scratch, pressing, or the like, of the window due to the touch, and this effect may be significant in a flexible display device using the window made of the flexible material.

By way of summation and review, in a capacitive type touch panel, in the case in which an object or conductor, such as a finger, a pen, a stylus, etc., is positioned in the vicinity of an upper window or touches the upper window, a voltage drop may generated to detect a touch position, thereby inputting a command or graphic information designated by a user. The display device itself may be bent, folded, or rolled. A window may be attached to the touch panel, and a flexible display device that may be bent, folded, or rolled may have a window made of plastic so as to have flexibility. The window made of the plastic may have low hardness. Thus, when the touch is made by applying force onto such a window using the finger or pen, a scratch, indentation, etc. may be generated on the window.

As described above, embodiments relate to a display device including a protecting layer for preventing damage to a window due to a touch, and a method for protecting a window thereof. Embodiments may provide a display device having advantages of preventing generation of a scratch or pressing on a window attached to the display device due to a touch.

Further, embodiments may provide a method for protecting a window of a display device by including a shape memory polymer layer disposed on the window and controlling the shape memory polymer layer.

As described above, in the display device according to an embodiment, the protecting layer is on the window, making it possible to prevent the generation of the scratch or the pressing due to the touch.

In addition, as described above, in the method for protecting a window of a display device according to an embodiment, in the case in which the touch is sensed on the window, the control signal is output to the shape memory polymer layer disposed on the window, thereby making it possible to restore the shape of the touch point.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A touch-enabled display device, comprising:
a display panel for displaying an image, a touch sensitive region being disposed at a first surface of the display panel;
a window on the display panel and covering the touch sensitive region; and
a protecting layer on the window, the protecting layer including a shape memory polymer layer.

2. The display device as claimed in claim 1, wherein the shape memory polymer layer is made of a flexible material, and restores its shape when an electrical signal is applied thereto.

3. The display device as claimed in claim 2, wherein:
the display device is made of a flexible material, and
the electrical signal is applied to the shape memory polymer layer in the case in which an object touches the protecting layer.

4. The display device as claimed in claim 3, wherein:
the shape memory polymer layer is configured of a plurality of unit cells, and
the plurality of unit cells are arranged in a lattice structure on the window.

5. The display device as claimed in claim 4, wherein the electrical signal is applied to each of the plurality of unit cells.

6. The display device as claimed in claim 3, wherein the protecting layer further includes a wiring part applying the electrical signal to the shape memory polymer layer.

7. The display device as claimed in claim 6, further comprising a controlling unit controlling the wiring part so that the electrical signal is applied to a region corresponding to a touch point by the object in the shape memory polymer layer.

8. The display device as claimed in claim 7, wherein:
the touch sensitive region is in a touch panel that includes a sensing unit sensing the touch point, and
the controlling unit applies the electrical signal through the wiring part depending on information on the touch point transferred from the sensing unit.

9. The display device as claimed in claim 8, wherein the sensing unit senses a touch prediction point as the touch point just before the object touches the protecting layer.

10. The display device as claimed in claim 3, wherein:
the display device is foldable,
the electrical signal is not applied to the shape memory polymer layer in a state in which the display device is folded, and
the electrical signal is applied to the shape memory polymer layer in a state in which the display device is unfolded.

11. The display device as claimed in claim 1, further comprising a polarizer facing a surface of the display panel.

12. The display device as claimed in claim 1, wherein the protecting layer is an outermost layer of the display device so as to be directly contacted by a user.

13. A method for protecting a window of a display device so as to prevent the window from being damaged when an object touches the display device over the window, the display device including a display panel and a touch sensitive region, a window on the display panel, and a shape memory polymer layer on the window, the method comprising:
sensing the touch over the window by the object; and
transferring a control signal to the shape memory polymer layer such that the shape memory polymer layer restores its shape.

14. The method as claimed in claim 13, wherein, in the sensing of the touch, a touch prediction point is sensed just before the object touches the display device over the window.

15. The method as claimed in claim 13, wherein:
the sensing of the touch includes calculating a coordinate value of a touch point, and
in the transferring of the control signal, the control signal is transferred to a region corresponding to the coordinate value in the shape memory polymer layer.

16. The method as claimed in claim 15, wherein:
the shape memory polymer layer restores its shape when an electrical signal is applied thereto, and
in the transferring of the control signal, the electrical signal is applied to the shape memory polymer layer.

17. The method as claimed in claim 16, wherein:
the shape memory polymer layer is configured of a plurality of unit cells, and the plurality of unit cells are arranged in a lattice structure on the window, and
in the transferring of the control signal, the electrical signal is applied to unit cells of a region corresponding to the touch point in the shape memory polymer layer.
